(19) United States
(12) Patent Application Publication
(10) Pub. No.: US 2015/0142358 A1
(43) Pub. Date: May 21, 2015

(54) RAPID INTERROGATION METHOD FOR ELASTIC WAVE RESONANT DEVICES

(71) Applicant: SENSEOR, Valbonne (FR)

(72) Inventor: Jean-Michel FRIEDT, BESANCON (FR)

(21) Appl. No.: 14/543,800

(22) Filed: Nov. 17, 2014

(30) Foreign Application Priority Data
Nov. 18, 2013 (FR) 1361246

(51) Int. Cl. G01R 23/04

(52) U.S. Cl. CPC G01R 23/04
USPC 702/75

(57) ABSTRACT

A method for interrogating an elastic wave device includes probing the response of a piezoelectric resonant device at a single frequency alternately on either side of a previously determined first resonance frequency, to characterize this resonance frequency characteristic of the measured physical quantity, by correlating this single measurement with a previously performed measurement.

### CROSS-REFERENCE TO RELATED APPLICATION

This application claims priority to foreign French patent application No. FR 1361246, filed on Nov. 18, 2013, the disclosure of which is incorporated by reference in its entirety.

### FIELD OF THE INVENTION

The field of the invention is that of elastic wave resonant devices that can be remotely interrogated via a radiofrequency wireless link. These devices can be used notably in the context of sensors.

### BACKGROUND

Such sensors are known to be used, for example, as temperature or pressure sensors and generally comprise at least one resonator comprising a microstructure deposited on the surface of a piezoelectric substrate. An example of a sensor can typically comprise two transducers with interdigital electrode combs placed between reflector arrays. The reflector arrays behave like mirrors and there are therefore resonance frequencies for which the return path in the cavity is equal to an integer number of wavelengths. The resonance modes for these frequencies are excited by the transducer placed between the mirrors.

This type of sensor can be remotely interrogated, by connecting the input of the transducer to a radiofrequency RF antenna. When the antenna receives an electromagnetic signal, the latter gives birth to waves on the surface of the substrate which are themselves reconverted into electromagnetic energy on the antenna. Thus, the device made up of a set of resonators connected to an antenna has a response to the resonance frequencies of the resonators that can be remotely measured. It is thus possible to produce sensors that can be remotely interrogated. This possibility is a significant advantage of the surface acoustic waves and can be used notably in the context of tyre pressure sensors. It is in fact advantageous in this type of application to be able to place the sensor in the tyre while the interrogation electronics are installed on board the vehicle.

According to the known art, remote interrogation systems use interrogation signals in the form of pulses (typically of approximately 25 μs duration) which pass via an emitting antenna to a receiving antenna connected to the surface wave sensor hereinafter in the description called SAW sensor.

A preferred frequency band for this type of system is the ISM band, ISM standing for “Industrial, Scientific, Medical”, the centre frequency of which is the frequency of 433.9 megahertz with an associated bandwidth of 1.7 megahertz (MHz).

Generally, an SAW sensor that can be remotely interrogated and its interrogation system can comprise, as illustrated in FIG. 1 in the simplified case of a single transducer:
an interrogation system 2;
at least one resonator 1 comprising:
   an antenna 100;
   a transducer with interdigital electrode comb 11 and an SAW resonant cavity 13 characterized by its centre frequency F and its quality factor Q, corresponding to the ratio between the centre frequency and the pass bandwidth. The cavity 13 comprises two series of reflectors evenly spaced apart by a distance d. The transducer is connected to the antenna 100.

The interrogator 2 sends a long radiofrequency pulse to charge the resonator 1. When the emission stops, the resonator discharges on its own resonance frequency with a time constant τ equal to Q/(πF). This discharge of the resonator constitutes the return echo detected by the receiver of the interrogator. A spectral analysis then makes it possible to re-establish the frequency of the resonator which constitutes its identification. This analysis can be performed by algorithms based on Fourier transformation, for example of FFT type, FFT standing for Fast Fourier Transform. This type of processing by spectral analysis is particularly complex.

An alternative to this complex processing has been previously demonstrated by the applicant and consists in probing the response of a piezoelectric resonant device as long as it exhibits an abrupt variation of its reflection coefficient as a function of the frequency, at only two frequencies on either side of the resonance frequency to characterize this resonance frequency characteristic of the measured physical quantity (Patent Application FR 2 958 417 and the paper by J. M Friedt, C. Droit, S. Ballandras, S. Alzuaga, G. Martin & P. Sandoz, Remote vibration measurement: a wireless passive surface acoustic wave resonator fast probing strategy, Rev. Sci. Instrum. 83, p.055001 (2012)).

With respect to this prior art, and to further refine this type of interrogation method, the applicant has sought to double the information refresh rate.

However, for this, probing on a single transfer function point is insufficient as illustrated by FIG. 2. This figure highlights, based on the curve C₀ corresponding to an initial transfer function, the two possible trends at a subsequent instant, namely: an attenuation of the signal represented by the curve C₁ or a shifting of the signal from the resonance frequency represented by the curve C₂.

In effect, in FIG. 2, starting from the initial condition of the transfer function represented by the curve C₀ (resonance frequency f0, characterization at the two frequencies f1 and f2), probing the response at a subsequent instant at a single frequency f2 does not make it possible to distinguish two possible trends of the transfer function, namely a lowering of the power returned by the sensor (response attenuated if the sensor moves away from the measurement electronics) or a shift in the resonance frequency (corresponding to a variation of the physical quantity). These two conditions will involve the same measurement, namely the circle represented.

It is thus not possible to separate the contribution of the link budget (the sensor approaches or moves away from the reader) from the measured physical quantity (the resonance frequency shifts away from the probed frequency).

### SUMMARY OF THE INVENTION

To resolve this problem, the applicant proposes an interrogation method, probing a single point of the transfer function of the resonant device now at the frequency lower than the resonance frequency: frequency f1, and now at the frequency higher than the resonance frequency: frequency f2.

The difference between these two quantities makes it possible to lock the emitted power in order to optimize the received radiofrequency power, while the hypothesis that the preceding measurement point (over or under resonance) remains unchanged at the time of the complementary measurement (under or over resonance) makes it possible to double the sampling frequency for identifying the resonance frequency of the device.

This condition observes the sampling theorem which indicates that it is impossible to know the trend of the quantity measured at the first frequency during the measurement on the second frequency: if the first point were to shift, it would be a question of a variation of the physical quantity at a speed greater than the measurement bandwidth, involving spectral aliasing.

The refreshing of the information concerning the estimation of the resonance frequency f0 after each measurement, now at the frequency f1, now at the frequency f2, does not therefore handicap the accuracy of the measurement but doubles the bandwidth by comparison to information refreshed after the two measurements of the responses at the frequency f1 and at the frequency f2 as proposed in the Patent Application FR 2 958 417.

More specifically, the subject of the present invention is a method for remotely interrogating an elastic wave resonator, that makes it possible to determine the resonance frequency of said resonator exhibiting a resonance curve defined by design of said resonator, characterized in that it comprises the following steps:

a preliminary step of scanning, at interrogation frequency, said resonator in a frequency range determined by design of said resonator, that makes it possible to rapidly determine a resonance curve centred on a preliminary resonance frequency fr₀ lying between a lower preliminary frequency frₚᵢ and a higher preliminary frequency frₚₛ defined at mid-height of said resonance curve of said resonator, by the detection of the response signal amplitude of said resonator;

a first set of preliminary steps comprising:
a first preliminary step of a first pair of interrogations of said resonator at a so-called lower first frequency f_{1,1} and at a so-called higher second frequency f_{2,1} such that: f_{1,1}=fr_{0-f}ₘ/2 and f_{2,1}=fr₀+fₘ/2, with fₘ<frₚₛ−frₚᵢ, making it possible to define a first pair of amplitudes of a first reception signal and of a second reception signal Pf_{1,1} and Pf_{2,1};
a second preliminary step comprising the determination of the difference in the amplitudes of the first and second signals Δ(Pf_{1,1}−Pf_{2,1}), said difference being negatively or positively signed;
a third preliminary step making it possible to define a first resonance frequency fr₁ locked onto said signed amplitudes difference and fulfilling the following equation: fr₁=fr₀+K*[Δ(Pf_{1,1}−Pf_{2,1})−Ca], with Ca being a locking setpoint and K a constant;

a series of steps comprising:
the interrogation of said resonator at a so-called lower frequency f_{1,2k} of rank 2k in the series (or at a so-called higher frequency f_{2,2k} of rank 2k in the series) with k being an integer greater than 1, following the interrogation of said resonator at a so-called higher frequency f_{2,2k-1} of rank 2k−1 in the series (or at a so-called lower frequency f_{1,2k-1} of rank 2k−1 in the series), such that: f_{1,2}=fr₂ₖ₋₁−fₘ/2 (or f_{2,2k}=fr₂ₖ₋₁+fₘ/2), making it possible to define the amplitude of a reception signal Pf_{1,2k} (or that of a signal Pf_{2,2k});
the determination of the difference in the amplitudes of the signals:
Δ(Pf_{1,2k}−Pf_{2,2k-1}) [or Δ(Pf_{1,2k-1}−Pf_{2,2k})], said difference being negatively or positively signed;
   the frequency fr₂ₖ being locked onto the amplitude difference
Δ(Pf_{1,2k}−Pf_{2,2k-1}) [or Δ(Pf_{1,2k-1}−Pf_{2,2k})], according to the following equation:

fᵣ₂ₖ=fr₂ₖ₋₁+K[Δ(Pf_{1,2k}−Pf₂ₖ−Pf_{2,2k-1})−Ca]

[fᵣ₂ₖ=fᵣ₂ₖ₋₁+K[Δ(Pf_{1,2k-1}−Pf_{2,2k})−Ca]];

the next step comprising:
the interrogation of said resonator at a so-called higher frequency f_{2,2k+1} of rank 2k+1 in the series (or at a so-called lower frequency f_{1,2k+1} of rank 2k+1) in the series, with k being an integer greater than 1, such that:
f_{2,2k+1}=fr₂ₖ+fₘ/2 (or f_{1,2k+1}=fr₂ₖ−fₘ/2), making it possible to define the amplitude of a reception signal Pf_{2,2k+1} (or that of a signal Pf_{1,2k+1});
   the determination of the difference in the amplitudes of the signals:
Δ(Pf_{2,2k+1}−Pf_{1,2k}) [or Δ(Pf_{2,2k}−Pf_{1,2k+1})], said difference being negatively or positively signed;

the frequency fr₂ₖ₊₁ being locked onto the amplitude difference
Δ(Pf_{2,2k+1}−Pf_{1,2k}) [or Δ(Pf_{2,2k}−Pf_{1,2k+1})] according to the following equation:

f_{r 2k+1}=f_{r 2k}+K[Δ(Pf_{2,2k+1}−Pf_{1,2k})−Ca]

[or fᵣ₂ₖ₊₁=f_{r 2k}+K[Δ(Pf_{2,2k}−Pf_{1,2k+1})−Ca]]

so as to obtain a determined resonance frequency fr₂ₖ₊₁ from a frequency fr₂ₖ such that the signed amplitudes difference:
Δ(Pf_{2,2k+1}−Pf_{1,2k}) [or Δ(Pf_{2,2k}−Pf_{1,2k+1})] is equal to the locking setpoint Ca.

According to a variant of the invention, the preliminary step of scanning, at interrogation frequency, said resonator in a frequency band making it possible to rapidly determine a first resonance frequency frₒ of said resonator is performed with a frequency interval equal to approximately a third of the width at mid-height of the resonance curve.

According to a variant of the invention, the frequency band is an ISM band, and more particularly that centred at 433.9 MHz.

According to a variant of the invention, the frequency fₘ is less than several tens of kilohertz.

According to a variant of the invention, the interrogation refresh rate is of the order of a few kilohertz and reaches the maximum bandwidth accessible by a resonator.

According to a variant of the invention, the interrogation refresh rate is of the order of a few kilohertz to reach the maximum accessible refresh frequency of 16.6 kHz by a transducer with reduced spectral bulk (resonator) at 434 MHz for a quality factor of 10 000.

According to a variant of the invention, the locking setpoint is zero.

According to a variant of the invention, the constant K is equal to 1.

Another subject of the invention is a device implementing the interrogation method according to the invention, characterized in that it comprises:
a reconfigurable radiofrequency source;
a microcontroller for reconfiguring said source;
means for receiving and digitally processing the amplitude of the reception signal.

### BRIEF DESCRIPTION OF THE DRAWINGS

The invention will be better understood, and other advantages will become apparent, on reading the following description given as a nonlimiting example and using the figures in which:

FIG. 1 illustrates the principle of interrogation of an SAW sensor according to the prior art;

FIG. 2 illustrates two possible trends of the transfer function at a given instant and the two conditions at a subsequent instant, namely the attenuation of the signal or the shift of the resonance frequency;

FIG. 3 illustrates the preliminary step of scanning at a frequency making it possible to determine the frequencies fᵣₚᵢ and fᵣₚₛ;

FIG. 4 illustrates an exemplary device that makes it possible to qualify the measurement bandwidth of a surface elastic wave resonator;

FIG. 5 illustrates the measurement of the response of a surface elastic wave resonator in the context of the interrogation method of the present invention.

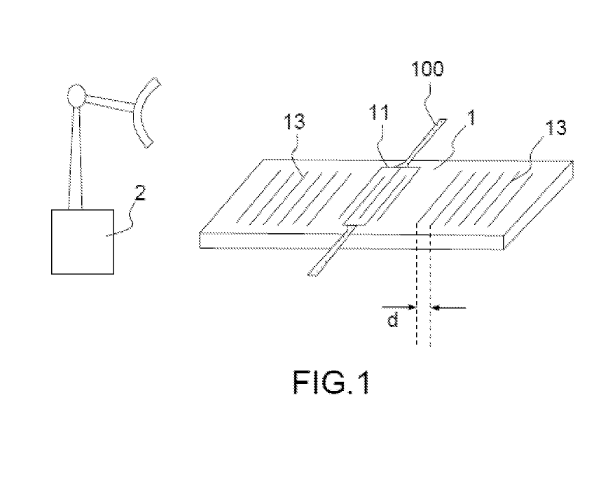

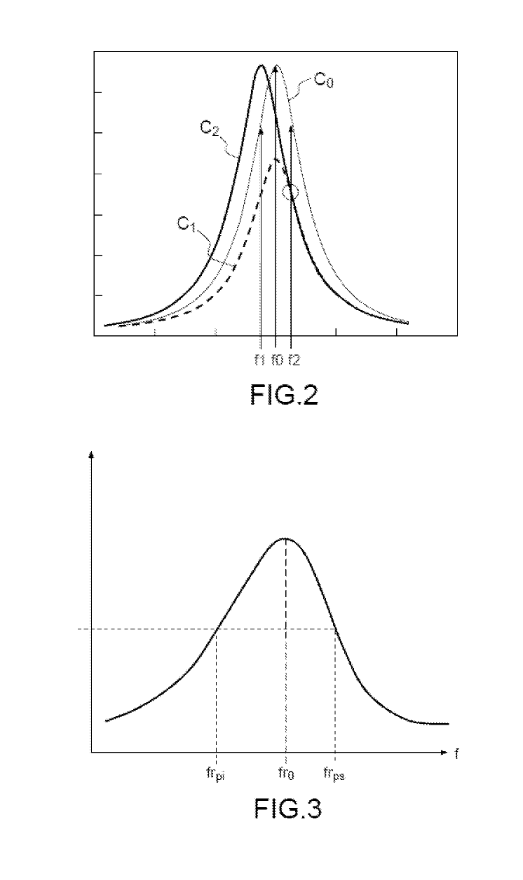

### DETAILED DESCRIPTION

According to the present invention, the interrogation method thus comprises a preliminary step of scanning, at interrogation frequency, said resonator in a frequency range known by the very design of the resonator concerned and that allows for the rapid determination of a first resonance frequency fr₀ of said resonator by detecting the amplitude of the response signal of said resonator. Typically, it will be able to be advantageous for numerous applications to be positioned in the ISM band cited previously (or another ISM band compatible with the use of radiofrequency resonators, in particular those with elastic waves).

FIG. 3 illustrates such a curve on which it is possible to define the preliminary resonance frequency and the two frequencies frₚᵢ and frₚₛ that make it possible to determine the frequency fₘ chosen to be less than the difference: frₚₛ−frₚₛ

It should be noted that the choice of the separation of the interrogation frequencies is made according to a trade-off between the returned power and the measurement accuracy. In effect, the more distant these frequencies are from the resonance frequency, the lower the power returned by the sensor, but the more accurate the measurement.

The applicant has found that the influence of the frequency fₘ does not seem to affect the resolution of the measurement when it is between 1 kHz and 50 kHz. However, choosing an excessively high frequency fₘ degrades the range of the measurement, the resonator having little effectiveness far from its resonance. Typically, it will be possible to choose, from the ISM band centred at 433.9 MHz, a frequency fₘ of the order of 10 kHz.

The interrogation method of the invention is then performed as follows.

In a first phase, a set of preliminary steps is carried out:
in a first preliminary step, the interrogation is performed at a first frequency f_{1,1} and at a second frequency f_{2,1} such that: f_{1,1}=fr₀−fₘ/2 and f_{2,1}=fr₀+fₘ/2, making it possible to define a first pair of amplitudes Pf_{1,1} and Pf_{2,1} of a first reception signal and of a second reception signal;
in a second preliminary step, the difference in the amplitudes Δ(Pf_{1,1}−Pf_{2,1} ) is determined, said difference being signed;
in a third preliminary step, a first resonance frequency fr₁ is defined that is locked onto said signed amplitudes difference and that fulfils the following equation:

fr₁=fr₀+K*[Δ(Pf_{1,1}−Pf_{2,1})−Ca],

with Ca being a locking setpoint and K a constant.

The interrogation method of the present invention then comprises the successive steps:
the frequency f_{2,2}=fr₁+fₘ/2 can be calculated;
this frequency f_{2,2}=fr₁+fₘ/2 is used to probe in order to obtain the power Pf_{2,2} at this frequency;
a frequency fr₂ is again determined by using this new probed power Pf_{2,2}, correlated with the preceding probed power Pf_{1,1}.

Thus, step by step, the series of preceding steps is reiterated, correlating a new interrogation with a preceding interrogation.

It should be noted that, in the present description, the method is described subject to the hypothesis that the probing is done at the frequency f_{2,2}, but an identical method could equally be applied in the case of a probing performed at the frequency f_{1,2}=fr₁−fₘ/2.

The frequencies f_{1,2k+1} and the frequencies f_{2,2k+2} are then probed successively and alternately so as to implement the method of the present invention based on a succession of a single interrogation and no longer two as in the method described in the Patent Application FR 2 958 417.

In these successive phases, the values listed in Table 1 below, as an illustration in which the probed amplitudes are indicated in bold, are determined.

TABLE 1

| | | | | |
|---|---|---|---|---|
| f_{1,1} | f_{2,1} | Pf_{1,1} | Pf_{2,1} | fr₁ = fr₀ + K[Δ(Pf_{1,1} − Pf_{2,1}) − Ca] |
| | f_{2,2} | Pf_{1,1} | Pf_{2,2} | fr₂ = fr₁ + K[Δ(Pf_{1,1} − Pf_{2,2}) − Ca] |
| f_{1,3} | | Pf_{1,3} | Pf_{2,2} | fr₃ = fr₂ + K[Δ(Pf_{1,3} − Pf_{2,2}) − Ca] |
| | f_{2,4} | Pf_{1,3} | Pf_{2,4} | fr₄ = fr₃ + K[Δ(Pf_{1,3} − Pf_{2,4}) − Ca] |
| | f_{2,2k} | Pf_{1,2k-1} | Pf_{2,2k} | fr₂ₖ = fr₂ₖ₋₁ + K[Δ(Pf_{1,2k-1} − Pf_{2,2k}) − Ca] |

with k being an integer and:
f_{1,3}=fr₂−fₘ/2
f_{2,4}=fr₃+fₘ/2
f_{2,2k}=fr₂ₖ₊₁+fₘ/2

The method continues in this way until a resonance frequency value fr₂ₖ₊₂ is achieved, such that the difference in the signed amplitudes:

Pf_{1,2k-1}−Pf_{2,2k} is equal to the value Ca.

For example, the value Ca can be chosen to be equal to 0.

With Ca equal to 0, the iteration method is terminated when the condition:

Pf_{1,2k-1}−Pf_{2,2k}=0

Similarly, by probing from a first frequency f_{1,2}, the Table 2 below can be created:

| | | | | |
|---|---|---|---|---|
| f_{1,1} | f_{2,1} | Pf_{1,1} | Pf_{2,1} | fr₁ = fr₀ + K[Δ(Pf_{1,1} − Pf_{2,1}) − Ca] |
| f_{1,2} | | Pf_{1,2} | Pf_{2,1} | fr₂ = fr₁ + K[Δ(Pf_{1,2} − Pf_{2,1}) − Ca] |
| | f_{2,3} | Pf_{1,2} | Pf_{2,3} | fr₃ = fr₂ + K[Δ(Pf_{1,3} − Pf_{2,3}) − Ca] |
| f_{1,4} | | Pf_{1,4} | Pf_{2,3} | fr₄ = fr₃ + K[Δ(Pf_{1,4} − Pf_{2,3}) − Ca] |
| | . . . | | . . . | . . . |
| | f_{2,2k} | Pf_{1,2k-1} | Pf_{2,2k} | fr₂ₖ = fr₂ₖ₋₁ + K[Δ(Pf_{1,2k} − Pf_{2,2k-1}) − Ca] |

Thus, and according to the invention, the signal received for the first frequency f₁₁=fr₀−fₘ/2 contains a total power (or amplitude) information item corresponding to an average value and a contribution of modulation that can be considered as “virtual” at low frequency. The signal received at the second frequency f_{2,1}=fr₀+fₘ/2 contains a total power (or amplitude) information item corresponding to an average value and a contribution of modulation that can be considered to be “virtual” at high frequency.

The contribution of the average value is eliminated when calculating the difference in the powers received at the frequencies f_{1,1} and f_{2,1} in order to extract only the contribution of the modulation signal. The difference in the powers received at each frequency provides an information item for which the sign will depend on the position relative to the frequency fr₀. Thus, according to the invention, it is proposed to perform an iterative function that makes it possible to cancel the abovementioned remainder. This step can be performed by a dichotomy method, by a Newton method or any other method that makes it possible to speed up the convergence of the iterative process.

Thus, any method capable of determining the zero of a function is particularly suitable in this case: the dichotomy method is an approach that consists in reducing the search interval for a zero of the function processed by comparison of the signs of this function after estimation. The samples are always taken such that their sign is opposite. The interval is divided into two then the new interval for which the new samples are of opposite signs is identified. The process is continued until the convergence criterion is observed. For its part, the Newton method is based on the use of the first order Taylor series in the vicinity of the zero to be identified. Each time a new sample is taken, the first derivative of the curve is calculated for the sample furthest away from the zero and the first derivative is used to deduce an estimation thereof.

The process converges after a number of iterations that become smaller as the curve becomes more regular and monotonous in the vicinity of the point sought. These examples are provided by way of illustration and can advantageously be replaced by more effective methods (Müller, etc.). A bibliographic reference that is useful in this regard is: A. Angot, Compléments de mathématiques, Masson Ed., 6^{th} Ed, 1982, and, internationally, Abramowitz and Stegun, Handbook of Mathematical Functions, on line http://www.math.ucla.edu/˜cbm/aands/.

A locking of the frequency fᵣ₀ which coincides with the resonance frequency of the interrogated sensor is thus performed. This locking can be likened to a phase locked loop whose characteristics of stability and of accuracy in the detection of the target frequency are better than the elements of this open loop measurement.

To implement the interrogation method of the present invention, it is advantageous to use an interrogator in monostatic configuration (with the electronics and the antenna shared between the transmitter and the receiver so as to reduce the bulk and the costs of synchronization between the transmitter and the receiver) that can be of frequency scanning pulsed RADAR type. This interrogator comprises a microcontroller responsible for applying a locking loop alternately to one of the two frequencies according to the process described hereinbelow:

a radiofrequency pulse at the desired frequency fr₂ₖ is transmitted for, for example, 30 μs, i.e. 5 time constants of the resonator;

knowing the measurement which has been done previously at a prior frequency, f_{r 2k-1}, fr₂ₖ−fr₂ₖ₋₁K[Δ(Pf_{1,2k-1}−Pf_{2,2k})−Ca], which would balance the response (corresponding to the power returned by the SAW transducer) at the frequencies
fr₂ₖ₋₁ et fr₂ₖ, is calculated;

a voltage (DAC) is then supplied that is proportional to this estimation of the duly determined frequency.

Typically, the frequency fₘ/2 can be a few kilohertz, i.e. within the range of the targeted applications, approximately ⅛ of the width at mid-height.

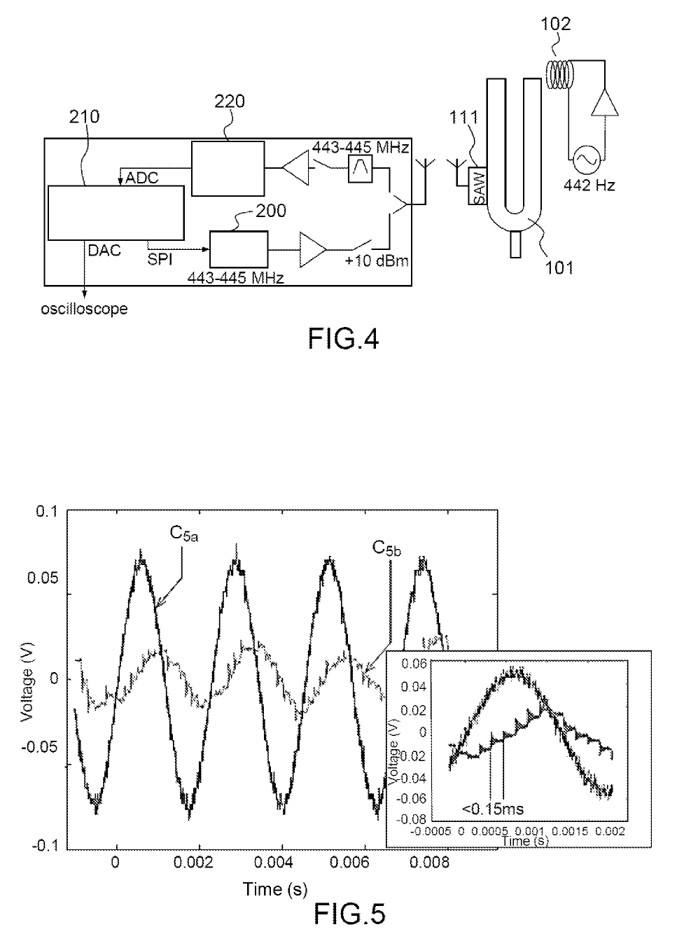

FIG. 4 illustrates an exemplary device that makes it possible to qualify the measurement bandwidth of the surface elastic wave resonator. It is an experimental device that makes it possible to qualify the measurement bandwidth of a surface elastic wave resonator 111 SAW, fixed to the base of the arm of a tuning fork 101 excited by an electromagnet 102. The method for the measurements of the resonance frequency of the SAW uses a reconfigurable radiofrequency source 200 (Direct Digital Synthesizer-DDS) configured by a microcontroller 210. The power returned by the SAW sensor for each probed frequency is detected by a detector 220 and digitized (ADC) for digital processing of the signal and definition of the next frequency f_{1,2k} or f_{2,2k}, to be transmitted in order to remain close (under or over respectively) to the resonance frequency. This is a musical tuning fork (nominal resonance frequency of 440 Hz) fitted with a quartz surface elastic wave resonator glued to the base of one of its arms. This resonator behaves like a strain gauge, whose resonance frequency (around 434 MHz, in the European Industrial, Scientific and Medical (ISM) band) varies with the strain transmitted from the arm of the tuning fork to the quartz substrate. Thus, the quartz resonator sees its resonance frequency vary with the movement of the arm of the tuning fork. In order to facilitate the experimental approach by observing a stationary regime, the musical tuning fork is excited by magnetic induction by an electromagnet powered by a sinusoidal signal generated by a frequency synthesizer whose frequency is close to the resonance frequency of the tuning fork (442 Hz).

The result of this measurement is illustrated in FIG. 5, indicating a refreshing of the information transmitted to the user, of 6800 Hz. Given a charging time of the resonator of 30 μs and a discharging time of equal duration (time constant of Q/π periods of the resonator, with Q the quality factor), probing the response at a frequency takes 60 μs, i.e. a maximum refresh rate of 16.6 KHz.

The curve C₅ₐ relates to the excitation of the tuning fork close to the resonance frequency of the resonator, the curve C_{5b} relating to the measurement of the response of the resonator. The zoom illustrates the information refresh frequency of 6800 Hz in this implementation of the algorithm.

Such an experimental implementation on microcontroller also necessitates:
the experimental reconfiguration of the frequency source needed to generate the radiofrequency probe signal at f_{1,2k-1} then f_{2,2k};
the storage in memory of the measurements and their digital processing;
the programming of a digital-analogue converter to retranscribe a voltage proportional to the resonance frequency deduced from the calculation.

These operations explain a refresh frequency of the order of a third of the maximum accessible frequency. An implementation on dedicated digital architecture (ASIC, FPGA) makes it possible to reach the maximum bandwidth by reducing the digital signal processing time.

Thus, according to the method of the present invention, the use of the prior value of the power returned by the sensor combined with the new power measurement according to the laws explained previously, thus alternating measurement and refreshing of the quantity which is measured and supplied to the user, makes it possible to double the measurement speed compared to the method that is the subject of the Patent Application FR 2 958 417.

1. A method for remotely interrogating an elastic wave resonator, that makes it possible to determine the resonance frequency of said resonator exhibiting a resonance curve defined by design of said resonator, comprising the following steps:
a preliminary step of scanning, at interrogation frequency, said resonator in a frequency range determined by design of said resonator, that makes it possible to rapidly determine a resonance curve centred on a preliminary resonance frequency fr₀ lying between a lower preliminary frequency frₚᵢ and a higher preliminary frequency frₚₛ defined at mid-height of said resonance curve of said resonator, by the detection of the response signal amplitude of said resonator;
a first set of preliminary steps comprising:
a first preliminary step of a first pair of interrogations of said resonator at a so-called lower first frequency f_{1,1} and at a so-called higher second frequency f_{2,1} such that: f_{1,1}=fr₀=fₘ/2 and f_{2,1}=fr₀+fₘ/2, with fₘ<frₚₛ−frₚᵢ, making it possible to define a first pair of amplitudes of a first reception signal and of a second reception signal Pf_{1,1} and Pf_{2,1};
a second preliminary step comprising the determination of the difference in the amplitudes of the first and second signals Δ(Pf_{1,1}−Pf_{2,1}), said difference being negatively or positively signed;
a third preliminary step making it possible to define a first resonance frequency fr₁ locked onto said signed amplitudes difference and fulfilling the following equation:
fr₁=fr₀+K*[Δ(Pf_{1,1}−Pf_{2,1})−Ca],
with Ca being a locking setpoint and K a constant;
a series of steps comprising:
the interrogation of said resonator at a so-called lower frequency f_{1,2k} of rank 2k in the series (or at a so-called higher frequency f_{2,2k} of rank 2k in the series) with k being an integer greater than 1, following the interrogation of said resonator at a so-called higher frequency f_{2,2k-1} of rank 2k−1 in the series (or at a so-called lower frequency f_{1,2k-1} of rank 2k−1 in the series), such that: f_{1,2k}=fr₂ₖ₋₁−fₘ/2 (or f_{2,2k}=fr₂ₖ₋₁+fₘ/2), making it possible to define the amplitude of a reception signal Pf_{1,2k} (or that of a signal Pf_{2,2k});
the determination of the difference in the amplitudes of the signals:
Δ(Pf_{1,2k}−Pf_{2,2k-1}) [or Δ(Pf_{1,2k-1}−Pf_{2,2k})], said difference being negatively or positively signed;
the frequency fr₂ₖ being locked onto the amplitude difference Δ(Pf_{1,2k}−Pf_{2,2k-1}) [or Δ(Pf_{1,2k-1}−Pf_{2,2k})] according to the following equation:
f_{r 2k}=fr₂ₖ₋₁+K[Δ(Pf_{1,2k}−Pf _{2,2k-1})−Ca]
[or f_{r 2k}=f_{r 2k-}₁K[Δ(Pf_{1,2k-1}−Pf_{2,2k})−Ca]];
the next step comprising:
the interrogation of said resonator at a so-called higher frequency f_{2,2k+1} of rank 2k+1 in the series (or at a so-called lower frequency f_{1,2+1} of rank 2k+1) in the series, with k being an integer greater than 1, such that:
f_{2,2k+1}=fr₂ₖ+fₘ/2 (or =fr_{1,2k+1}=fₘ/2), making it possible to define the amplitude of a reception signal Pf_{2,2k+1} (or that of a signal Pf_{1,2k+1});
the determination of the difference in the amplitudes of the signals:
Δ(Pf_{2,2k+1}−Pf_{1,2k}) [or Δ(Pf_{2,2k}−Pf_{1,2k+1})], said difference being negatively or positively signed;
the frequency fr₂ₖ₊₁ being locked onto the amplitude difference Δ(Pf_{2,2k+1}−Pf_{1,2k}) [or Δ(Pf_{2,2k}−Pf_{1,2k+1})] according to the following equation:
f_{r 2k+1}=f_{r 2k}+K[Δ(Pf_{2,2k+1}−Pf_{1,2k})−Ca]
[or f_{r 2k+}1=f_{r 2k}+K[Δ(Pf_{2,2k}−Pf_{1,2k+1})−Ca]]
so as to obtain a determined resonance frequency fr₂ₖ₊₁ from a frequency fr₂ₖ such that the signed amplitudes difference:
Δ(Pf_{2,2k+1}−Pf_{1,2k}) [or Δ(Pf_{2,2k}−Pf_{1,2k+1})] is equal to the locking setpoint Ca.

2. The method for interrogating a resonator according to claim 1, in which the preliminary step of scanning, at interrogation frequency, said resonator in a frequency band making it possible to rapidly determine a first resonance frequency (fr₀) of said resonator is performed with a frequency interval equal to approximately a third of the width at mid-height of the resonance curve.

3. The method for interrogating a resonator according to claim 1, in which the frequency band is an ISM band, and more particularly that centred at 433.9 MHz.

4. The method for interrogating a resonator according to claim 1, in which the frequency fₘ is less than several tens of kilohertz.

5. The method for interrogating a resonator according to claim 1, in which the interrogation refresh rate is of the order of a few kilohertz and reaches the maximum bandwidth accessible by a resonator.

6. The method for interrogating a resonator according to claim 1, in which the locking setpoint is zero.

7. The method for interrogating a resonator according to claim 1, in which the constant K is equal to 1.

8. A device implementing the interrogation method according to claim 1, comprising:
a reconfigurable radiofrequency source;
a microcontroller for reconfiguring said source;
means for receiving and digitally processing the amplitude of the reception signal.
